(19) United States
(12) Patent Application Publication
(10) Pub. No.: US 2011/0057655 A1
(43) Pub. Date: Mar. 10, 2011

(54) SOFTWARE FOR ADJUSTING MAGNETIC HOMOGENEITY, METHOD FOR ADJUSTING MAGNETIC HOMOGENEITY, MAGNET DEVICE, AND MAGNETIC RESONANCE IMAGING APPARATUS

(75) Inventors: Ryuya Ando, Hitachi (JP); Mitsushi Abe, Hitachinaka (JP); Shogo Maeno, Hitachi (JP)

(73) Assignees: HITACHI, LTD., Tokyo (JP); HITACHI MEDICAL CORPORATION, Tokyo (JP)

(21) Appl. No.: 12/991,475

(22) PCT Filed: May 8, 2009
(86) PCT No.: PCT/JP2009/058712

§ 371 Date: Nov. 8, 2010

(30) Foreign Application Priority Data
May 9, 2008 (JP) 2008-123345

(51) Int. Cl. G01R 33/44

(52) U.S. Cl. 324/318

(57) ABSTRACT

On the basis of the magnetic field intensity distribution of a magnetic field space (3), in order to homogenize the distribution, the positions and the volumes of magnetic material shims (such as shim bolts (27)) which have to be arranged on shim trays (17, 18) are first computed on a minute computational grid. Subsequently, from the distributions of the computed positions and volumes of the magnetic material shims, the local maximum values and local minimum values thereof are extracted, and the distribution areas of the volumes of the magnetic material shims with each value as the center are extracted. Then, the volumes of the magnetic materials distributed in the distribution areas are added. Finally, the results of the addition are displayed with the positions of corresponding local maximum values or the positions of corresponding local minimum values.

### TECHNICAL FIELD

The present invention relates to software for adjusting magnetic homogeneity, a method for adjusting magnetic homogeneity, a magnetic device, and a magnetic resonance imaging apparatus.

### BACKGROUND ART

Using a nuclear magnetic resonance phenomenon that occurs when a specimen placed in a homogeneous static magnetic field is irradiated with high frequency pulses, a magnetic resonance imaging (MRI) apparatus can obtain an image representing the physical and chemical properties of the specimen, and is particularly used for medical purposes. The MRI apparatus mainly includes a magnetic field generation source for applying a homogeneous static magnetic field in an imaging region into which the specimen is carried, an RF coil for irradiating the imaging region with high frequency pulses, a receiving coil for receiving a response from the imaging region, and a gradient magnetic field coil for applying a gradient magnetic field to provide the imaging region with position information of a resonance phenomenon.

In the MRI apparatus, one of the factors for improving the image quality is an improvement in the static magnetic field homogeneity in the imaging region. In designing and manufacturing of a magnetic device used for the MRI apparatus, magnetic field homogeneity adjustment is performed at the respective stages of designing, assembling, and installing in order to make a static magnetic field, which is generated in the imaging region by a magnetic field generation source, homogeneous.

Among these, the magnetic field homogeneity adjustment performed at the installing stage can be realized by adding or removing magnetic field homogeneity adjusting pieces (magnetic shims) of a magnetic material to/from a magnetic device, for example, when a magnetic field inhomogeneity component has been caused by a manufacturing error or the surrounding environment. For example, in a magnetic device of a type that forms an imaging region and a homogeneous magnetic field space thereof between magnetic field generation sources (magnetic poles) vertically facing each other, a structure is formed, in general, by providing and disposing a magnetic field homogeneity adjustment mechanism (means), which is called a shim tray, in a tray shape of a non-magnetic material in each of the spaces sandwiched by the respective magnetic poles and respective gradient magnetic field coils disposed inside with respect to the magnetic poles (namely, on the imaging region side) (for example, refer to Patent Document 1).

On the other hand, in a magnetic device of a type that incorporates a plurality of superconducting coils to be a magnetic field generation source in a double cylindrical container and forms an imaging region inside thereof and a homogeneous magnetic filed space along the axial direction of the cylinder, a structure is formed, in general, by providing a shim tray (magnetic field homogeneity adjuster) in the space sandwiched by a gradient magnetic field coil disposed on the inner circumferential side of the container and the inner circumferential surface of the container, or by incorporating a shim tray in the gradient magnetic field coil (for example, refer to Patent Document 2).

Consideration on where and how many magnetic shims are to be disposed on these shim trays is, in general, an optimization problem having an objective function for the magnetic field homogeneity in the imaging region, and disposition of magnetic shims is often determined by a linear optimization method or a method modified therefrom, using a given magnetic field distribution (for example, refer to Patent Document 3).

### PRIOR ART DOCUMENTS

### Patent Documents

Patent Document 1: JP 3733441 B2
Patent Document 2: JP 2007-202900 A
Patent Document 3: JP 2003-167941 A

### Non-Patent Document

Non-patent Document 1: authors Haruo Yanai, Kei Takeuchi ‘Projection Matrix, Generalized Inverse Matrix and Singular Value Decomposition’, UP Applied Mathematics Library, University of Tokyo Press, 1983

### SUMMARY OF THE INVENTION

### Problems to be Solved by the Invention

As a magnetic field homogeneity adjuster, a structure that allows disposition of magnetic shims (with a large volume) as many as possible per unit area makes a high magnetic field homogeneity adjustment capacity. This is because a large change in the magnetic field strength can be generated in an imaging region by a large volume of magnetic shims. In order to easily realize this, a method was considered that makes a large number of screw holes through a shim tray and screws magnetic material shims called shim bolts into these screw holes. In this method, by finely disposing screw holes, it is possible to dispose shim bolts as many as the number of the screw holes, and as a result, a large number of magnetic shims can be disposed. Further, by disposing screw holes at fine relative positions to each other, formation of a spatially fine magnetic filed distribution can be expected.

However, in order to realize a homogeneous magnetic field, in a case of individually managing a large number of screw holes and thus applying an optimization method such as a linear programming method to determine disposition of shim bolts, an elaborate work of screwing optimum shim bolts into the respective holes without an error is required. Assuming that, for example, several thousands of screw holes have been formed through one shim tray, a person to be engaged in the magnetic field homogeneity adjustment work needs to accurately array screws (shim bolts) necessary for the respective screw holes, which makes the work efficiency extremely low.

In order to improve this work efficiency, for example, a method of setting the number to a required minimum and thus decreasing the number of screw holes to be managed was considered. In this situation, it was also considered to make the diameter of screw holes to be provided through a shim tray large, however, the size of a shim bolt, in other words, the size of a screw hole cannot be made quite large, taking into account handling shim bolts for magnetic field homogeneity adjustment in a strong magnetic field generated by a magnetic device. Consequently, there is a problem that a sufficient magnetic field homogeneity adjustment capacity cannot be obtained.

Therefore, a method was considered, as a method for improvement, that divides a shim tray into several regions in advance such that each region includes a plurality of screw holes through the shim tray without a change in the diameter nor the number of holes, adds the volumes of shim bolts to be disposed at the screw holes in each region, and then displays the individual total volumes in the respective regions together. Herein, the above-described regions can be designed to attain a spatial accuracy sufficient for magnetic field homogeneity adjustment. It is necessary to set the regions to have a size matching a magnetic field homogeneity adjustment that is the finest adjustment expected at the time of adjusting the installation of a magnetic device. In such a manner, the work efficiency can be made higher than that for a case of individually managing a large number of screw holes.

However, because the size of these regions is normalized merely to ensure a sufficient spatial accuracy of the magnetic field distribution as described above, the size inevitably becomes small, in other words, the number of regions still remains large. If such region dividing is performed, even in a case of performing a sort of general (in other words, not-detailed) magnetic field homogeneity adjustment that does not require a high spatial accuracy of magnetic field distribution, it is necessary to finely dispose shim bolts in many regions, which causes a problem of a low work efficiency.

An object of the present invention is to provide software for adjusting magnetic homogeneity, a method for adjusting magnetic homogeneity, a magnetic device, and an MRI apparatus that contribute to improvement in the work efficiency in performing general magnetic field homogeneity adjustment which does not require, as described above, a significantly fine spatial accuracy of the magnetic field distribution.

### Means for Solving the Problems

To solve the above-described problems, in accordance with the present invention, the positions and volumes of magnetic members (for example, shim bolts) to be disposed on a shim tray are calculated first on a computational mesh, based on the magnetic field strength distribution in a magnetic field space, to make the magnetic field strength distribution homogeneous. Subsequently, from the distribution of the calculated positions and volumes of the magnetic members, the local maximum values and the local minimum values thereof are extracted; the volume distribution regions of the magnetic members, with the centers thereof respectively at the positions of the extracted local maximum and minimum values, are extracted; and the volumes of the magnetic members distributed in these distribution regions are added in the respective regions. Finally, results of these calculations are displayed together with the corresponding local maximum value positions or the corresponding local minimum value positions.

Preferably, this method of extraction of distribution regions is desired to be a method that establishes the regions while checking the relationship with respect to the mass between adjacent nodes on the computational mesh and sequentially expanding the regions.

Further, the mass display method, described above, preferably displays the positions and the mass to be visually recognizable on a screen that displays the shape of the shim tray.

### Advantages of the Invention

According to the present invention, it is possible to provide software for adjusting magnetic homogeneity, a method for adjusting magnetic homogeneity, a magnetic device, and an MRI apparatus that contribute to improvement in the work efficiency in performing general magnetic field homogeneity adjustment which does not require a significantly fine spatial accuracy of the magnetic field distribution.

### BRIEF DESCRIPTION OF THE DRAWINGS

FIG. 1A is a perspective view showing an example of a magnetic device as an object for magnetic field homogeneity adjustment in accordance with the present invention;

FIG. 1B is a longitudinal sectional view of the magnetic device shown in FIG. 1A;

FIG. 2 is an enlarged longitudinal sectional view showing the details of the upper magnetic pole of the magnetic device shown in FIG. 1;

FIG. 3A is an enlarged perspective view showing a shim tray (magnetic field homogeneity adjuster) of the magnetic device shown in FIG. 1;

FIG. 3B is a longitudinal cross-sectional schematic view of the shim tray;

FIG. 4 is a schematic view showing an example of computational mesh for calculating the volume distribution of shim bolts corresponding to the magnetic device shown in FIG. 1;

FIG. 5A is a distribution diagram showing, by contour lines, the distribution of magnetic moments of shim bolts calculated on a computational mesh shown in FIG. 4;

FIG. 5B is a graph showing the change in the value of the magnetic moments along the radial direction;

FIG. 6A and FIG. 6B are examples of a display of the volume distribution of the shim bolts calculated on the nodes of the computational mesh in a case where the volumes of the shim bolts are added in the regions of the orthogonal grid;

FIG. 7A and FIG. 7B are schematic views showing the concept of an algorithm for calculating the volume distribution regions with the initial points thereof at the respective peak positions, wherein the calculation is made from the volume distribution, of the shim bolts calculated on the nodes of the computational mesh;

FIG. 8A and FIG. 8B are diagrams showing an example of a display, wherein the volume distribution regions with the initial points thereof at the respective peak positions are calculated from the volume distribution of the shim bolts, the volume distribution having been calculated on the nodes of the computational mesh, and results of adding the mass in the respective regions are displayed;

FIG. 9 is a flow chart showing the procedure of magnetic field homogeneity adjustment using a method for adjusting magnetic homogeneity in accordance with the present invention;

FIG. 10 is an illustration showing a magnetic field distribution measurement device and a computer for magnetic field homogeneity adjustment;

FIG. 11 is a block diagram illustrating the operation of software for adjusting magnetic homogeneity;

FIG. 12 is a table used in display methods of shim bolt volume distribution, in a second embodiment in accordance with the present invention, corresponding to FIG. 6 in the first embodiment;

FIG. 13 is a table used in display methods of shim bolts volume distribution, in the second embodiment in accordance with the present invention, corresponding to FIG. 8 in the first embodiment;

FIG. 14 is a longitudinal sectional view showing the outline of a magnetic device of an MRI apparatus as an object for magnetic field homogeneity adjustment work as a third embodiment in accordance with the present invention; and

FIG. 15 is a schematic diagram showing an example of computational mesh for calculating the volume distribution of shim bolts corresponding to the magnetic device shown in FIG. 14.

### BEST MODES FOR CARRYING OUT THE INVENTION

Embodiments in accordance with the present invention will be described in detail, with reference to the accompanying drawings.

### First Embodiment

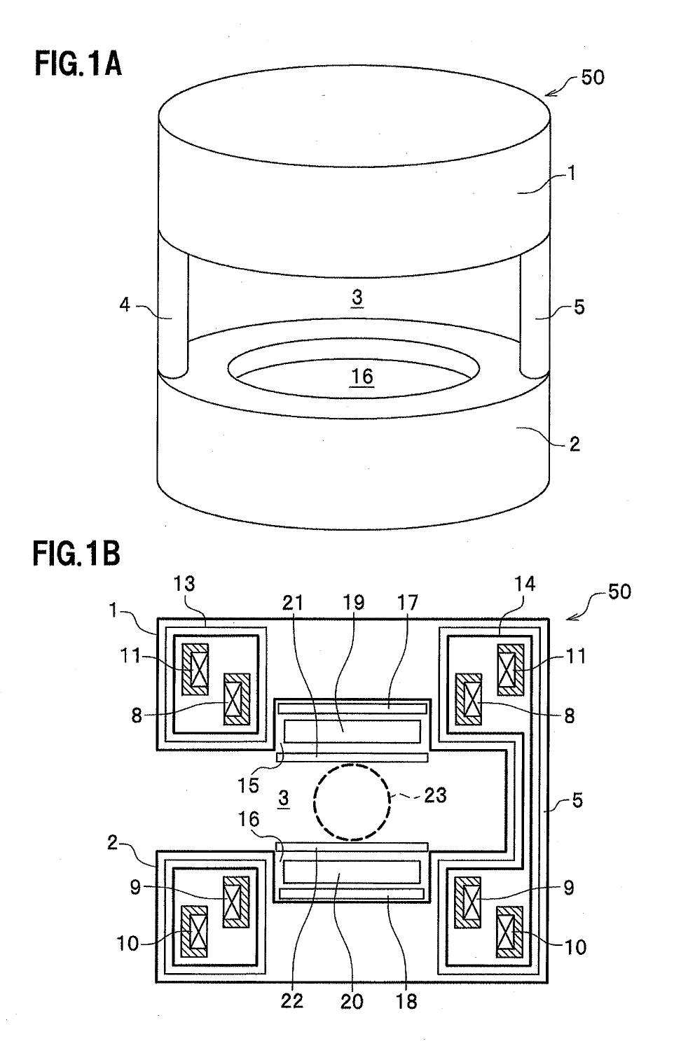

FIG. 1A is a perspective view showing an example of a magnetic device 50 as an object for magnetic field homogeneity adjustment in accordance with the present invention. FIG. 1B is a longitudinal sectional view of the magnetic device 50 shown in FIG. 1A.

As shown in FIG. 1A, as a magnetic field generation source of an MRI apparatus, the magnetic device 50 has a structure where an upper coil container 1 and a lower coil container 2 in a pair are disposed facing each other with coupling poles 4, 5 therebetween such as to form a magnetic field space 3. As shown in FIG. 1B, superconducting coils 8, 11 formed in a ring shape are housed in the upper coil container 1, and superconducting coils 9, 10 formed in a ring shape are housed in the lower coil container 2.

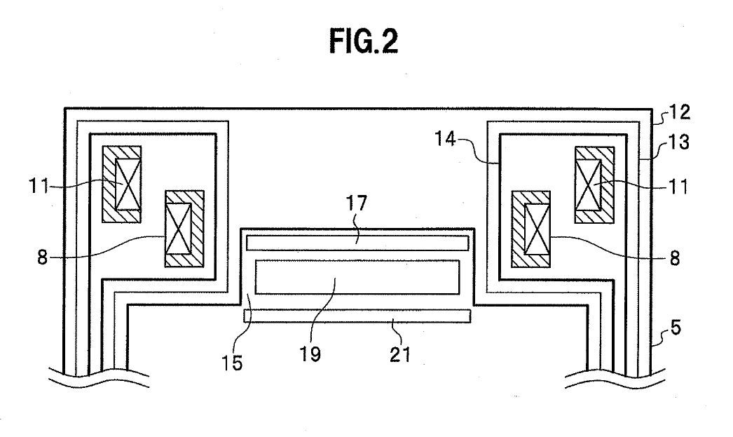

FIG. 2 is an enlarged longitudinal sectional view showing the details of the upper magnetic pole of the magnetic device 50 shown in FIG. 1.

As shown in FIG. 2, the upper coil container 1 includes, for example, a vacuum container 12 formed substantially in a cylindrical shape, a radiation shield 13 housed in the vacuum container 12, and a helium container 14 housed in the radiation shield 13. In the helium container 14, the superconducting coil (primary coil) 8 and the shield coil 11 formed in a ring shape are housed together with liquid helium (not shown) as superconducting refrigerant. FIG. 2 shows the upper coil container 1, and likewise the lower coil container 2 also has the same internal structure symmetrical to that of the upper coil container 1 with respect to the magnetic field space 3 (refer to FIGS. 1A and 1B).

Returning to FIG. 1B, the upper coil container 1 is formed with a cylindrical recess 15 on the surface thereof facing the magnetic field space 3. A shim tray 17 of a non-magnetic material, such as plastic or aluminum, is housed in the recess 15. A gradient magnetic field coil 19 is disposed on the magnetic field space 3 side of the shim tray 17, and an RF transmitting/receiving coil 21 is disposed between the magnetic field space 3 and the gradient magnetic field coil 19.

Likewise, the lower coil container 2 is formed with a cylindrical recess 16 on the surface thereof facing the magnetic field space 3. A shim tray 18 of a non-magnetic material is housed in the recess 16. A gradient magnetic field coil 20 is disposed on the magnetic field space 3 side of the shim tray 18, and an RF transmitting/receiving coil 22 is disposed between the magnetic field space 3 and the gradient magnetic field coil 20.

The superconducting coils 8, 9, 10, and 11 form an imaging region 23, which is a part of the magnetic field space 3, as a homogeneous magnetic field space. The superconducting coils (primary coils) 8, 9 generate the strongest magnetic field and form a static magnetic field along the vertical direction in the magnetic filed space 3. The shield coils 10, 11 are provided to prevent the magnetic field formed by the superconducting coils (primary coils) 8, 9 from leaking outside. Further, the gradient magnetic field coils 19, 20 form a dynamic magnetic field in the imaging region 23. The RF transmitting/receiving coils 21, 22 irradiate the imaging region 23 with an electromagnetic wave (radio wave) and receive the electromagnetic wave.

The superconducting coils 8, 9, 10, and 11 are disposed such as to generate a homogeneous magnetic field in the imaging region 23, as described above. If the superconducting coils 8, 9, 10, and 11 are insufficient to obtain necessary strength or homogeneity of the magnetic field, then ferromagnetic members (not shown), such as iron pieces (including iron alloy, the same hereinafter) or permanent magnets, are disposed (or removed from), for example, inside or outside the vacuum container 12, inside the radiation shield 13, or inside the helium container 14 to increase (or attenuate) the magnetic field strength or to improve the homogeneity. The above description has been made for a case of disposing four superconducting coils 8, 9, 10, and 11, however, more or fewer superconducting coils may be disposed.

In such a manner, the magnetic device 50 is designed such as to generate a homogeneous magnetic field, using the superconducting coils 8, 9, 10, and 11 and iron pieces or the like (not shown), however, in reality, an error magnetic field is generated in the imaging region 23 by an assembling error, effects by the installation environment, or the like. The shim trays 17, 18 are provided in order to remove this error magnetic field component.

From the surface of the upper coil container 1, the shim tray 17, the gradient magnetic field coil 19, and the RF transmitting/receiving coil 21 are disposed in this order. Likewise, from the surface of the lower coil container 2, the shim tray 18, the gradient magnetic field coil 20, and the RF transmitting/receiving coil 22 are disposed in this order. The gradient magnetic field coils 19, 20, and the RF transmitting/receiving coils 21, 22 are installed to be removable. The shim trays 17, 18 may be or may not be removable.

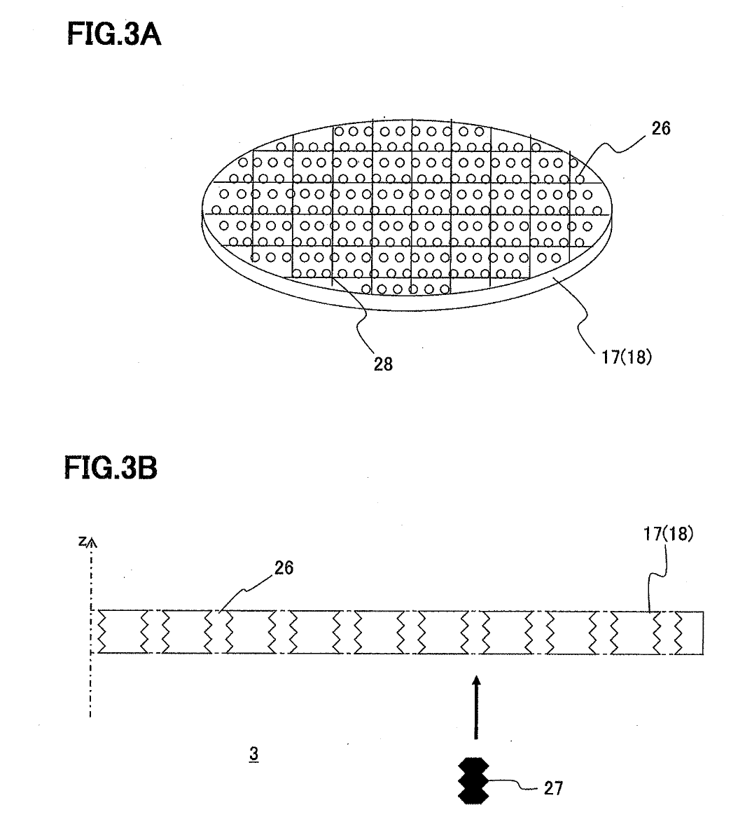

FIG. 3A is an enlarged perspective view showing a shim tray (magnetic field homogeneity adjuster) 17 (18) of the magnetic device 50 shown in FIG. 1, and FIG. 3B is a longitudinal cross-sectional schematic view of the shim tray 17 (18).

The shim trays 17, 18 have a shape of a disk or the like and are provided with a number of screw holes (female screw) 26 therethrough. In magnetic field homogeneity adjustment, when shim bolts 27, which are magnetic shims in a screw shape (male screw), are screwed into the screw holes 26, the shim trays 17, 18 are added with a magnetic material by the shim bolts 27. Shim bolts 27 are prepared in advance, having various volumes and shapes depending on the length and the machining method, and a worker for magnetic field homogeneity adjustment selects and uses appropriate shim bolts 27 with required volumes and shapes.

As shown in FIG. 3A, the surfaces of the shim trays 17, 18 are partitioned by grid lines 28 into small regions. The grid lines 28 are drawn such that plural screw holes 26 are included inside the respective grid sections. Although the shim bolts 27 has been described about a case of using magnetic shims in a screw shape, magnetic shims not in a screw shape may be used. Magnetic shims in various shapes, for example, a cylindrical shape, a prismatic shape, a conical shape, a pyramid shape, a plate shape, a rivet shape, and other shapes, can be suitably used, depending on the conditions.

The magnetic field homogeneity adjustment work means disposing shim bolts 27, which are necessary to make the magnetic field distribution in the imaging region 23 homogeneous, in the screw holes 26 provided through the shim trays 17, 18. Based on the measurement values of the magnetic field strength distribution in the imaging region (homogeneous magnetic field space) 23, software (software for adjusting magnetic homogeneity), which is installed on a computer, calculates at which positions and in what approximate volumes shim bolts 27 are to be disposed on the shim trays 17, 18 in order to obtain a desirable homogeneous magnetic field.

The algorithm of the software determining the disposition may be based on, for example, a numerical programming method such as a linear programming method, other optimization methods, and may be based on a method that solves an inverse problem. In the present embodiment, an algorithm according to the inverse problem solution method will be described as an example.

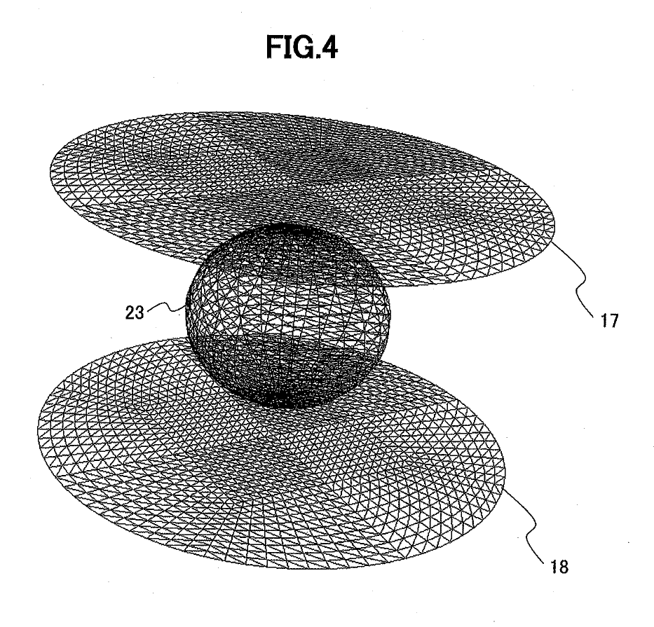

FIG. 4 is a schematic diagram showing an example of computational mesh for calculating the volume distribution of shim bolts 27 corresponding to the magnetic device 50 shown in FIG. 1.

First, the initial measurement is, as described later, performed in a state that shim bolts 27 are not disposed on the shim trays 17, 18, then measurement is repeated while shim bolts 27 are sequentially added, and thereby a predetermined magnetic field homogeneity is obtained. As shown in FIG. 4, the shim trays 17, 18, and the imaging region (the homogeneous magnetic field space) 23 are expressed by computational mesh. The nodes of the computational mesh of the shim trays 17, 18, for example, may match and may not match the positions of the screw holes 26 provided through the shim tray 17. On the other hand, the nodes of the computational mesh of the imaging region (the homogeneous magnetic field space) 23 are set in advance to match the positions for actual measurement of the magnetic field strength through magnetic field homogeneity adjustment work, or to match positions for calculating the magnetic field strength.

When a shim bolt 27 with a volume Vᵢ and a magnetic charge M is disposed at a certain node i on the computational mesh of the shim tray 17, 18, the shim bolt 27 causes a magnetic field strength B (i, j) at a certain adjacent node j in the imaging region (homogeneous magnetic field space) 23, the magnetic field strength B being proportional to the volume Vᵢ and the magnetic charge M.

Expression 1

B(i, j)∝VᵢM=mᵢ (1)

The symbol mᵢ represents the magnetic dipole moment of the shim bolt 27. Herein, the magnetic charge M is assumed to be constant. Accordingly, the distribution of the magnetic moments of the shim bolts 27 disposed at the respective nodes on the computational mesh of the shim tray 17, 18 is expressed by the following expression.

$$\begin{matrix}Expression 2 & \\ {m}^{->} = ( \begin{matrix}{m}_{1} \\ {m}_{2} \\ ⋮ \\ {m}_{n}\end{matrix} ) & ( 2 )\end{matrix}$$

The distribution of the magnetic field strengths created, by these, at the respective nodes on the computational mesh of the imaging region (the homogeneous magnetic field space) 23 is expressed by the following expression.

$$\begin{matrix}Expression 3 & \\ {b}^{->} = ( \begin{matrix}{b}_{1} \\ {b}_{2} \\ ⋮ \\ {b}_{l}\end{matrix} ) & ( 3 )\end{matrix}$$

Then, the relationship between the magnetic field distribution and the magnetic moment distribution is expressed by the following expression, representing the coefficient matrix by matrix A.

Expression 4

\vec{b}=A\vec{m} (4)

Applying a singular value decomposition method to the matrix A, a generalized inverse matrix A′ of the matrix A can be obtained. As a result, the following expression is obtained. The singular value decomposition method is, for example, the method described in the above-described “Non-patent Document 1”.

Expression 5

\vec{m}=A′\vec{b} (5)

That is, once the magnetic field distribution (to be generated) as a target is determined, required magnetic moment distribution can be calculated by calculating the matrix product between itself and the generalized inverse matrix A′ as shown in Expression (5). As described in the present invention, for a magnetic field homogeneity adjustment work, namely, a work for making the magnetic field distribution of the imaging region (homogeneous magnetic field space) 23 homogeneous, the target homogeneous magnetic field distribution is expressed by the following.

Expression 6

\vec{b}ᵤ (6)

Further, the measured values (or the calculated values) of the magnetic field distribution on the current imaging region (homogeneous magnetic field space) 23 are expressed by the following.

Expression 7

\vec{b}ₘ (7)

Then, the magnetic field distribution to be generated can be calculated by the following expression.

Expression 8

\vec{b}=\vec{b}ᵤ−\vec{b}ₘ (8)

If the magnetic moment distribution is obtained, then the volumes Vᵢ of shim bolts 27 corresponding to respective magnetic moments mᵢ can be simply calculated by the following expression from Expression (1).

Expression 9

Vᵢ=mᵢ/M (9)

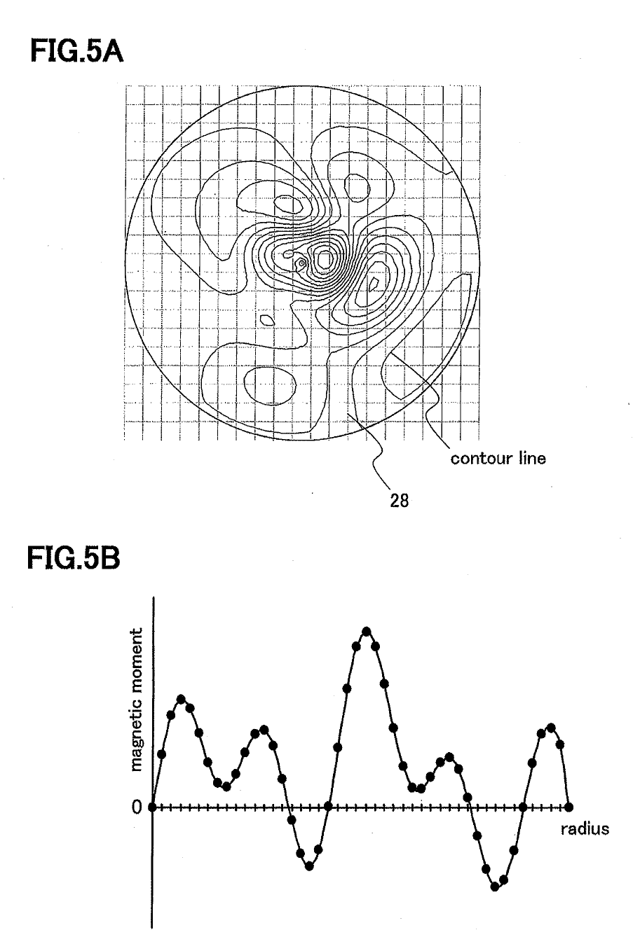

FIG. 5A is a distribution diagram showing, by contour lines, the distribution of magnetic moments of shim bolts 27 calculated on the computational mesh shown in FIG. 4, and FIG. 5B is a graph showing the change in the value of the magnetic moments along the radial direction.

More concretely, these show an example of the distribution of the magnetic moments obtained by Expression (5), wherein FIG. 5A shows an example that represents, by contour lines, the distribution of the magnetic moments mᵢ calculated on the shim tray 17 (or the shim tray 18), and FIG. 5B is a diagram schematically showing this distribution by a graph taking into account only one dimensional direction (radial direction).

In such a manner, the magnetic moments mᵢ are the amounts distributed at the respective nodes. Herein, a positive magnetic moment refers to a magnetic moment in the same direction as that of the magnetic field caused by the magnetic device 50, and a negative magnetic moment refers to a magnetic moment in the opposite direction to that of the magnetic field caused by the magnetic device 50.

As described above, reproducing the distribution of the magnetic moments (in other words, the volumes of the shim bolts 27) distributed at the respective nodes (or the respective screw holes 26) as it is on the shim trays 17, 18 makes the work efficiency significantly low due to a large number of nodes. In this situation, in order to increase the work efficiency, it is considered to define regions in a state of the grid lines (orthogonal grid) 28 such as to be a background shown in FIG. 5A, and to add the magnetic moments, at the nodes, that are present in the regions (for example, a region A) inside the respective grid sections. Herein, the total value m_{A} is expressed by the following expression.

### Expression 10

$${m}_{A} = {\sum }_{i ∈ A} {m}_{i} \qquad ( 10 )$$

Further, the volume V_{A} of the shim bolts 27 is obtained by the following expression.

$$\begin{matrix}Expression 11 & \\ {V}_{A} = \frac{{m}_{A}}{M} & ( 11 )\end{matrix}$$

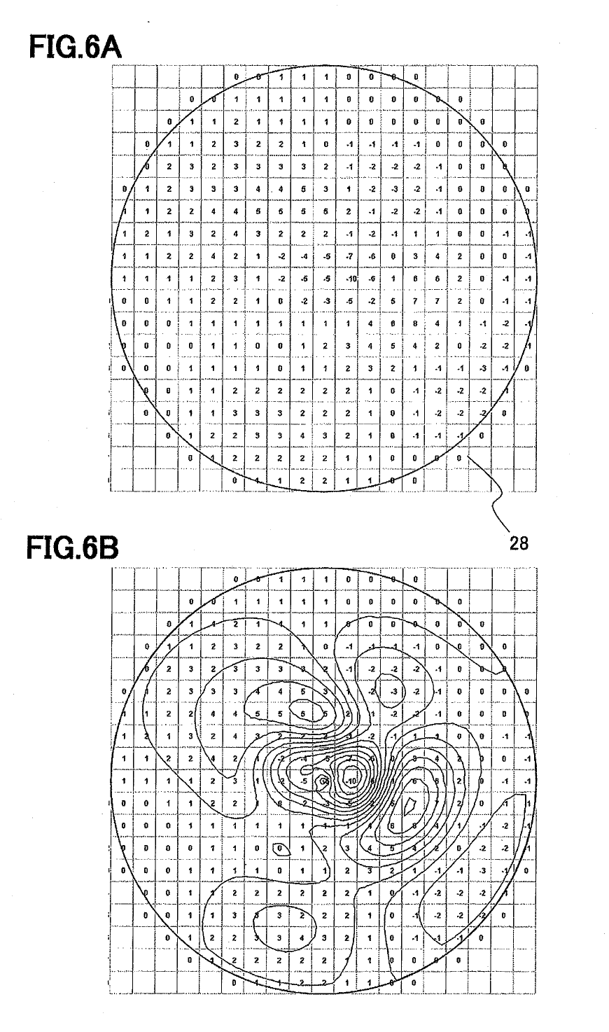

FIG. 6 is an example of a display of the volume distribution of the shim bolts calculated on the nodes of the computational mesh in a case where the volumes of the shim bolts are added in the respective regions of the orthogonal grid. FIG. 6(a) shows a case of displaying only numbers, and FIG. 6(b) shows a case of displaying the numbers together with contour lines shown in FIG. 5A.

The unit (dimension) of the respective numbers is, for example, the cubic centimeter, for representation of the volume of shim bolts 27. A positive number means that a magnetic moment whose value corresponds to the value of this number is to be given in the direction reinforcing the static magnetic field caused in this region by the magnetic device 50. Concretely, shim bolts 27 of ferromagnetic pieces (iron or the like) corresponding to the volume represented by this number are to be given. A negative number means that a magnetic moment corresponding to the value of this number is to be given in the direction attenuating the static magnetic field caused in this region by the magnetic device 50. Concretely, shim bolts 27 of permanent magnets with a strength corresponding to this number are to be disposed in the opposite direction to that of the static magnetic field caused by the magnetic device 50, or, if shim bolts 27 of ferromagnetic pieces are already disposed, these are to be removed. The size (area, shape) of each section partitioned by the grid lines (orthogonal grid) 28 is appropriately determined in advance such as to have a sufficient performance for magnetic field adjustment work, and is, for example, 50 millimeters square. By this method, the workability is improved compared with disposing a shim bolt/bolts 27 at each node.

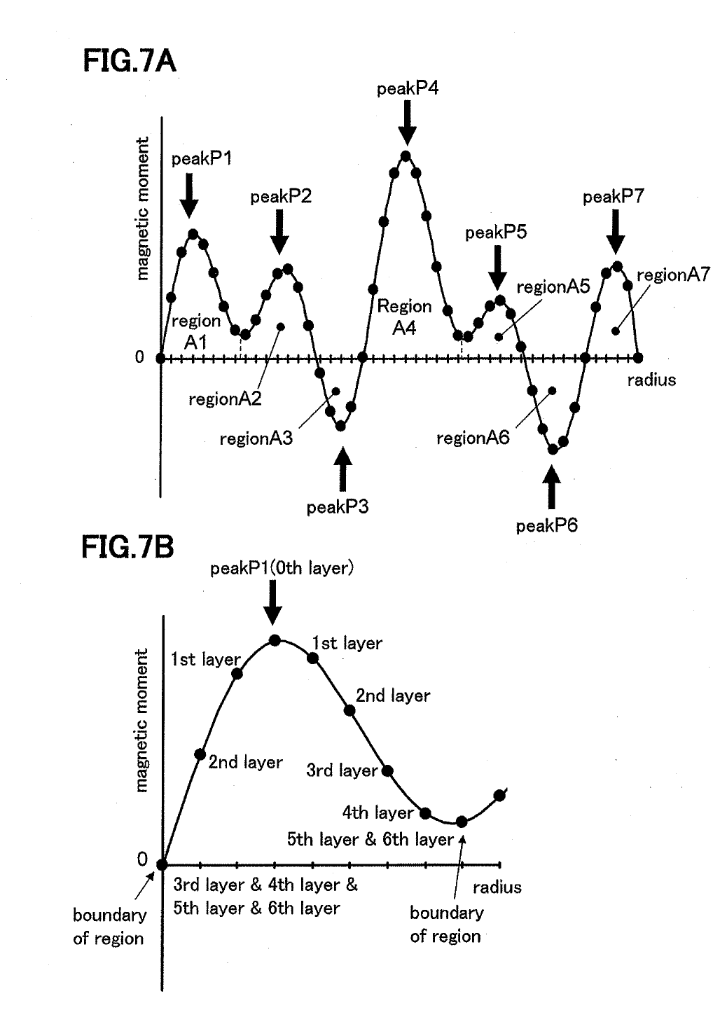

FIG. 7 is a schematic view showing the concept of an algorithm for calculating the volume distribution regions with the initial points thereof at the respective peak positions, wherein the calculation of the volume distribution regions is made from the volume distribution, of the shim bolts 27, calculated on the nodes of the computational mesh.

As shown in FIG. 6, by the above-described method, as it is necessary to dispose shim bolts 27, corresponding to the number of orthogonal grid sections, it is desired to decrease the number of man-hour of disposing shim bolts 27.

In this situation, as shown in FIG. 7, a region An where magnetic moments are distributed with the center at the peak position Pn is extracted, and the magnetic moments in the region An are added by Expression (10) and Expression (11). Although, two dimensional computation processing is performed in reality, the procedure is schematically viewed by a one-dimensional schematic view in FIG. 7 for simplifying the principle. In FIG. 7, the length in the radial direction is roughly divided into regions A1 to A7 with boundaries at the positions where the sign reverses or at the positions where the gradient reverses, and the corresponding peaks P1 to P7 are extracted. Accordingly, it is found that it is only required to dispose shim bolts 27 at the few peaks P1 to P7. In the present description, peaks and bottoms are not distinguished from each other, and both are expressed as peaks. That is, peaks include bottoms.

Expansion of this principle to a real two-dimensional computational mesh will be as follows.

First, all peak positions Pn are extracted from the distribution of magnetic moments. The magnetic moment at a certain node i will be represented by mᵢ, and the magnetic moment at each adjacent node j will be represented by mⱼ. If the following expression is satisfied for every adjacent node j, the node i is the peak position.

Expression 12

mᵢ>mⱼ>0 or mᵢ<mⱼ<0 (12)

Next, while checking the values of the magnetic moments at the adjacent nodes with initial points at the respective peak positions Pn, the boundaries of the regions An are determined as follows.
(1) The node corresponding to a peak position Pn is defined to be on the 0^{th} layer.
(2) Out of all nodes adjacent to a certain node k belonging to the n^{th} layer, the group of nodes except nodes having already been defined to be on the n^{th} or another layer is represented by C.
(3) If the peak position Pn has a positive magnetic moment with respect to all the nodes o belonging to the node group C, and the following expression is satisfied, then the nodes o are defined to be on the (n+1)^{th} layer.

Expression 13

0<mₖ<mₒ or mₒ<0 (13)

Further, if the peak position Pn has a negative magnetic moment, and the following expression is satisfied, then the nodes o are defined to be on the (n+1)^{th} layer.

Expression 14

mₒ<mₖ<0 or mₒ>0 (14)

If any one of nodes o do not satisfy these expressions, then redefinition is made such that the node k instead of the nodes o is defined to be on the (n+1)^{th} layer.
(4) The expressions (2) and (3) are repeated until all the nodes belonging to the n^{th} layer are redefined to be on the (n+1)^{th} layer.
(5) The group of nodes finally forming the outermost layer forms the boundary of the region An.

By the above-described procedure, regions An corresponding to the peak positions Pn are determined, as schematically shown in FIG. 7.

When the magnetic moment and the volume of the nodes belonging to the region An are calculated by Expression (10) and Expression (11), this volume V_{A}n is the volume of shim bolts 27 to be disposed in the region An. The worker is only required to dispose V_{A}n in the vicinity of the peak position Pn.

Concretely, in the vicinity of a peak position to be applied with a positive magnetic moment, shim bolts 27 of ferromagnetic pieces, iron for example, are to be disposed. In the vicinity of a peak position to be applied with a negative magnetic moment, shim bolts of permanent magnets are to be disposed in the direction for applying a negative magnetic moment, or, if there are already existing shim bolts 27, these are to be removed.

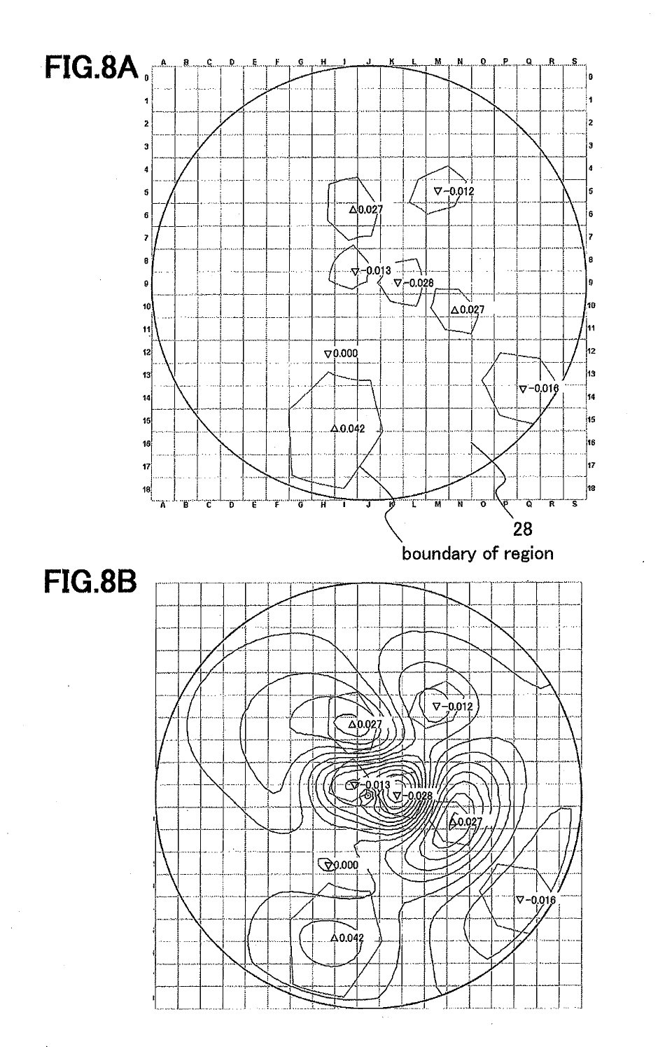

FIG. 8 is a diagram showing examples of displays, wherein the volume distribution regions with the initial points thereof at the respective peak positions are calculated from the volume distribution of the shim bolts, the volume distribution having been calculated on the nodes of the computational mesh, and wherein results of adding the mass in the respective regions are displayed. That is, these display examples illustrate the volumes of shim bolts 27 calculated by the above-described method. FIG. 8(a) is a case where only volumes and region boundaries are displayed, and FIG. 8(b) is a case where contour lines shown in FIG. 5A are displayed together.

The unit (dimension) of the respective numbers is, for example, cubic centimeter for representation of the volumes of shim bolts 27. In order to decrease work errors by intuitively expressing positive or negative of volumes, the symbols shown on the left side of the numbers represent positive amounts with a mark “Δ” and negative amounts with a mark “∇”. In order to recognizably notify a worker of positions to dispose shim bolts 27, it is desired that, for example, the shim trays 17, 18 are partitioned by the grid lines (orthogonal grid) 28, and coordinates, as shown in FIG. 8(a), are assigned.

When the above-described displays are made by magnetic field adjustment software, the worker is only required to perform disposition, for example, at seven positions in the case of the example shown in FIG. 8 (This number is no more than an example in FIG. 8, and the number is variable depending on the conditions or situations in real magnetic field homogeneity adjustment work.). Thus, the work efficiency is greatly improved compared with disposing the volumes calculated by Expression (9) at the respective nodes or performing disposition according to a volume display in a grid form as shown in FIG. 6. Further, a magnetic device 50 that uses such a method or an MRI apparatus using it enables reduction in time taken by installation adjustment, and thereby an inexpensive apparatus can be provided as a result.

The above-described method approximately determines regions An and the boundaries thereof. Accordingly, in order to improve the accuracy of magnetic field homogeneity adjustment, this magnetic field homogeneity adjustment is repeated plural times.

Next, the flow of magnetic field homogeneity adjustment work in accordance with the present invention will be described.

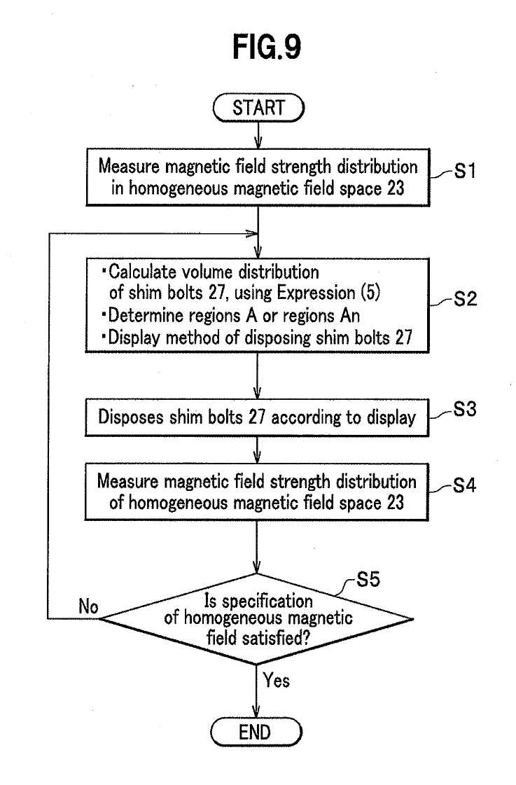

FIG. 9 is a flowchart showing the magnetic field homogeneity adjustment work in accordance with the present invention.

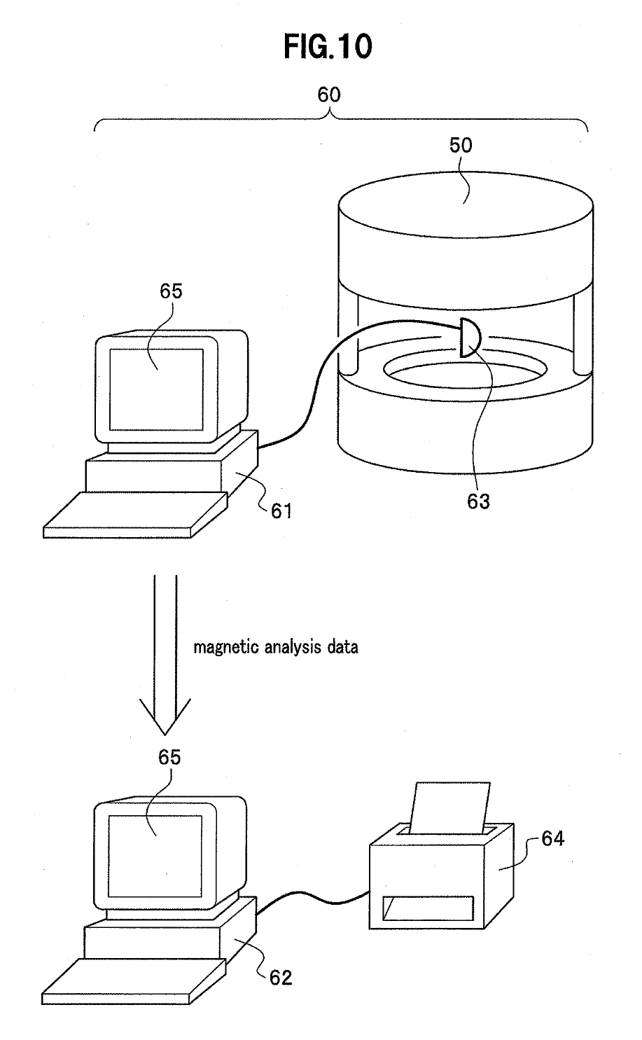

First, the magnetic field strength distribution in the imaging region (the homogeneous magnetic field space) 23 is measured (step S1). Concretely, a magnetic field distribution measurement device 60 operates, and a magnetic probe 63 obtains measurement signals (a measurement result). Based on this measurement result, a data obtaining computer 61 generates magnetic field analysis data (magnetic field distribution data 72) (described later with reference to FIG. 10).

Then, a magnetic field homogeneity adjustment computer 62 (described later with reference to FIG. 10)
calculates the volume distribution of shim bolts 27, using Expression (5)
determines regions A or regions An
displays a method of disposing shim bolts 27 (step S2).

Next, the worker disposes shim bolts 27 on the shim trays 17, 18, while having a view of the display on a display device 65 (refer to FIG. 10) (step S3).

Then, similarly to step S1, the magnetic field strength distribution of the imaging region (the homogeneous magnetic field space) 23 is measured (step S4).

Next, it is determined whether or not the specification of the homogeneous magnetic field is satisfied (step S5). That is, it is determined whether or not the magnetic field homogeneity of the imaging region (the homogeneous magnetic field space) 23 is within a predetermined value. More concretely, the magnetic field homogeneity adjustment computer 62 (refer to FIG. 10) determines whether or not the magnetic strength is within a predetermined range, based on the magnetic analysis data. If the specification of the homogeneous magnetic field is not satisfied (“No” in step S5), the above-described processing on and after step S2 is repeated. If the specification of the homogeneous magnetic field is satisfied (“Yes” in step S5), the magnetic field homogeneity adjustment work is terminated.

In this repeated process, if the display in FIG. 6 and the display in FIG. 8 are arbitrarily switchable, the worker can proceed the work, while appropriately changing detailed disposition of shim bolts 27 as shown in FIG. 6 and a sort of general disposition of shim bolts 27 as shown in FIG. 8.

FIG. 10 is an illustration of the magnetic field distribution measurement device 60 and the magnetic field homogeneity adjustment computer 62.

The magnetic field distribution measurement device 60 is provided with the magnetic probe 63 that is inserted into the imaging region (the homogeneous magnetic field space) 23 of the magnetic device 50 and detects the magnetic distribution, and the data obtaining computer 61 that is connected to the magnetic probe 63 and has the display device 65 and a data obtaining program installed thereon.

The magnetic field homogeneity adjustment computer 62 is a computer that includes the display device 65 and an output device 64, such as a printer, and has software for adjusting magnetic homogeneity installed thereon.

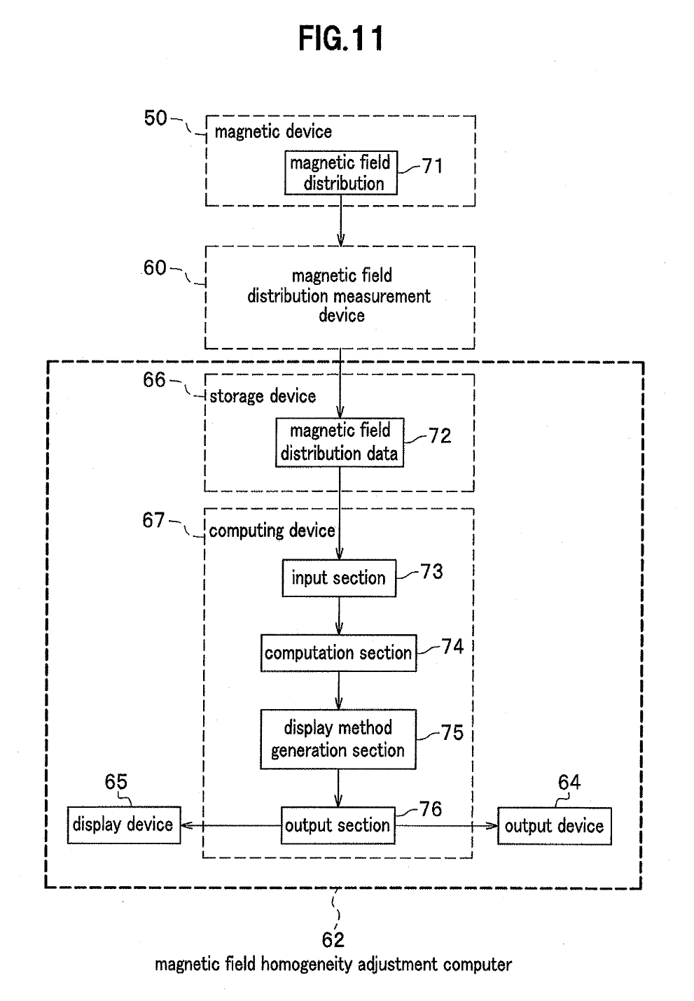

FIG. 11 is a block diagram illustrating the operation of the software for adjusting magnetic homogeneity.

The magnetic field homogeneity adjustment computer 62 includes a storage device 66, a computing device 67, a display device 65, and an output device 64. On the magnetic field homogeneity adjustment computer 62, the software for adjusting magnetic homogeneity is installed, and forms functions of an input section 73, a computation section 74, a display method generation section 75, and an output section 76.

FIG. 10 shows the data obtaining computer 61 and the magnetic field homogeneity adjustment computer 62 such that they are different computers. However, as it is sufficient if data obtaining software and software for adjusting magnetic homogeneity respectively operate, it is obvious that the computers 61 and 62 may be the same one, in other words, one computer used for the both purposes.

The operations from obtaining the magnetic field distribution to displaying shim bolts 27 to be disposed are carried out as follows.
(1) The magnetic device 50 is excited as rated.
(2) The magnetic field distribution measurement device 60 obtains magnetic field distribution data of the imaging region (homogeneous magnetic field space) 23 of the magnetic device 50. Concretely, while rotating the magnetic probe 63 having a number of detection sections (refer to FIG. 10), the magnetic field distribution measurement device 60 obtains magnetic field distribution 71 from the imaging region 23 of the magnetic device 50, and the data obtaining computer 61 generates magnetic field distribution data 72 from the magnetic field distribution 71.
(3) The magnetic field homogeneity adjustment computer 62 stores the magnetic field distribution data 72 into the storage device 66 by using the software for adjusting magnetic homogeneity.
(4) The input section 73 sequentially receives the magnetic field distribution data 72 from the storage device 66, and sends the magnetic field distribution data 72 to the computation device 67.
(5) The computation section 74 computes the volume distribution data of shim bolts 27 based on the magnetic field distribution data 72 having been read.
(6) The display method generation section 75 transmits this volume distribution data to the output section, according to a preset method.
(7) Based on the volume distribution data, the output section 76 displays the volume distribution on the display device 65 or outputs the volume distribution using the output device 64 such as a printer.
(8) The worker carries out magnetic field homogeneity adjustment work (the work of disposing magnetic members (shim bolts 27)), while having a view of this display or output result.

### Second Embodiment

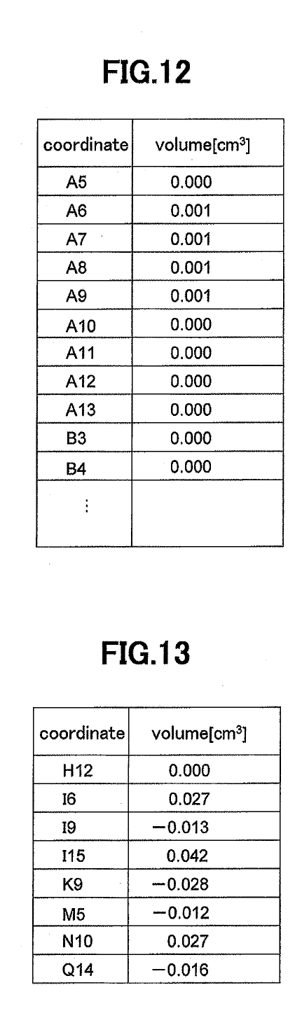

With reference to FIGS. 12 and 13, a display method by the software for adjusting magnetic homogeneity in a second embodiment in accordance with the present invention will be described.

FIG. 12 is a display example corresponding to FIG. 6 in the first embodiment, and FIG. 13 is a display example corresponding to FIG. 8. In such a manner, in the present embodiment, instead of displaying a distribution image of the magnetic field as shown in FIG. 6 or FIG. 8, the coordinates and the volumes of the disposition points are displayed in a form of a list. The present embodiment is the same as the first embodiment except display, and accordingly duplicate explanation will be omitted.

In such a manner, as the correspondence between the positions (coordinates) to dispose shim bolts 27 and the volumes thereof is clear even without drawing the positions in the magnetic field distribution, the workability is significantly improved while keeping the principle of adding the distributed volumes on the shim tray 17 (18).

### Third Embodiment

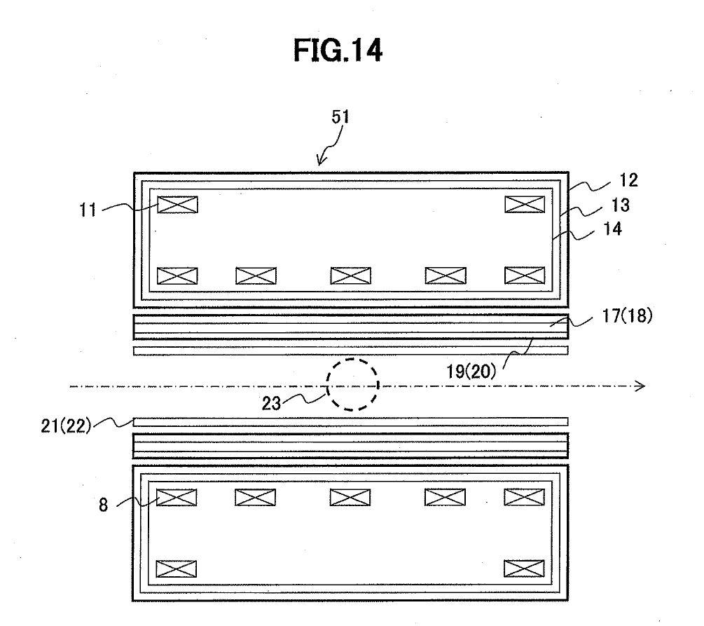

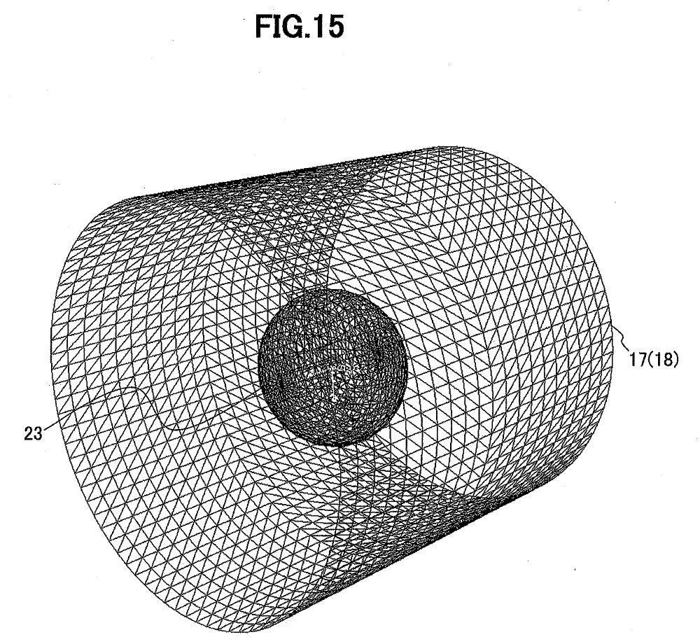

With reference to FIGS. 14 and 15, as a third embodiment in accordance with the present invention, another example of a magnetic device 51 and a magnetic field homogeneity adjuster of an MRI apparatus as an object will be described below.

FIG. 14 is a longitudinal sectional view showing the outline of the magnetic device 51 in the third embodiment in accordance with the present invention.

While the magnetic device 50 (refer to FIG. 1) as an object in the respective foregoing embodiments is a magnetic device 50 that generates a magnetic field in the perpendicular direction to the imaging region (the homogeneous magnetic field space) 23 by magnetic poles which are disposed facing vertically each other, the magnetic device 51 (refer to FIG. 14) in the present embodiment generates a magnetic field in the horizontal direction in an imaging region (a homogeneous magnetic field space) 23 by a group of superconducting coils incorporated inside a double cylindrical shape vacuum container 12, a radiation shield 13, and a helium container 14. The same symbols are assigned to configuration elements that can be substantially the same as those in the respective foregoing embodiments, and overlapping description will be omitted.

As shown in FIG. 14, in the magnetic device 51, a gradient magnetic field coil 19 is disposed on the inner circumference of the vacuum container 12 in the double cylindrical shape, and a shim tray 17 (18) is incorporated in the gradient magnetic field coil 19 (20). This structure is an example, and the shim tray 17 (18) may be disposed on the inner circumferential side of the gradient magnetic field coil 19 (20) and may be disposed on the outer circumferential side.

FIG. 15 is a conceptual diagram showing an example of computational mesh, corresponding to those in FIG. 4, for such a magnetic device 51.

By performing calculation which is similar to that conducted in the first embodiment, using such a computational mesh, magnetic field homogeneity adjustment work is all the same possible also on the magnetic device 51 with the structure shown in FIG. 14, and the work efficiency can also be improved.

In respective embodiments in accordance with the present invention, a worker for magnetic field homogeneity adjustment is only required to dispose shim bolts (magnetic shims) 27 in a minimum quantity at positions of a minimum requirement in respective stages of a magnetic field homogeneity adjustment work, which eliminates the necessity of managing all the positions of shim trays 17, 18 and disposing magnetic shims precisely at the respective positions, and thus the efficiency of the magnetic field homogeneity adjustment work can be significantly increased. Further, because a magnetic device 50 or the like using such a method or an MRI apparatus using such a apparatus can reduce the time for installation adjustment, it is possible to provide an inexpensive apparatus as a result.

### REFERENCE SYMBOLS

1 upper coil container
2 lower coil container
3 magnetic field space
4, 5 coupling pole
8, 9 primary coil
10, 11 shield coil
12 vacuum container
13 radiation shield
14 helium container
15, 16 vacuum container recess
17, 18 shim tray
19, 20 gradient magnetic field coil
21, 22 RF transmitting/receiving coil
23 imaging space (homogeneous magnetic field space)
26 screw hole
27 shim bolt (shim member, magnetic shim)
28 grid line (grid line of an orthogonal grid)

1. Software for adjusting magnetic homogeneity for a magnetic device having a magnetic field generation source for generating a magnetic field space and a magnetic field homogeneity adjuster for adjustment of magnetic field strength distribution formed in the magnetic field space to make the distribution homogeneous, the adjustment being performed by appropriately disposing adjustment magnetic members on the magnetic field homogeneity adjuster,
wherein the software instructs how to make adjustment that is to be performed on the magnetic field homogeneity adjuster by the magnetic members, based on the magnetic field strength distribution in the magnetic field space having been measured, so that the magnetic field strength distribution becomes homogeneous, the software comprising the steps, executed by a computer, of:
obtaining measurement data on the magnetic field strength distribution in the magnetic field space, wherein the data is measured through the magnetic field homogeneity adjuster; and
displaying a plurality of portions of the magnetic field homogeneity adjuster as portions in need of adjustment by the magnetic members on a display unit, based on the measurement data.

2. Software for adjusting magnetic homogeneity for a magnetic device having a magnetic field generation source for generating a magnetic field space and a magnetic field homogeneity adjuster for making magnetic field strength distribution, formed in the magnetic field space, homogeneous by disposing magnetic members outside the magnetic field space, wherein the software calculates and displays positions and volumes of the magnetic members to be disposed on the magnetic field homogeneity adjuster to make the magnetic field strength distribution homogeneous, based on the magnetic field strength distribution, the software comprising the steps, executed by a computer, of:
extracting, from distribution of volumes of magnetic members for making magnetic field strength distribution homogenous, the distribution of volumes being calculated on a computational mesh, respective distribution regions of the volumes with initial points of the regions at positions of local maximum values and at positions of local minimum values of the volumes;
adding the volumes of magnetic members distributed in the respective distribution regions; and
displaying the positions of the magnetic members and results of adding the volumes together with the corresponding positions of the local maximum values or the corresponding positions of the local minimum values.

3. The software for adjusting magnetic homogeneity according to claim 2, wherein the magnetic device generates the magnetic field space, by magnetic poles vertically facing each other, in a vertical direction between the magnetic poles.

4. The software for adjusting magnetic homogeneity according to claim 2, wherein the magnetic field homogeneity adjuster comprises disk formed non-magnetic shim trays disposed on surfaces of the magnetic poles and magnetic shims disposed on the shim trays.

5. The software for adjusting magnetic homogeneity according to claim 2, wherein, in the display step, the software enables arbitrarily switching between:
a method that displays the positions and the results of adding the volumes together with the corresponding positions of the local maximum values or the corresponding positions of the local minimum values, wherein the positions and the results of adding the volumes have been obtained by the extraction step of extracting the respective distribution regions of the volumes with the initial points of the regions at the positions of the local maximum values and at the positions of the local minimum values of the volumes, from the distribution of the volumes of the magnetic members for making the magnetic field strength distribution homogenous, the distribution of volumes having been calculated on the computational mesh, and the addition step of adding the volumes of the magnetic members distributed in the respective distribution regions; and
a method that partitions the magnetic field homogeneity adjuster into small regions in advance, adds the volumes of the magnetic members respectively in the small regions, and displays the volumes obtained by the addition.

6. The software for adjusting magnetic homogeneity according to claim 5, wherein coordinates are assigned to the small regions to identify respective positions thereof.

7. The software for adjusting magnetic homogeneity according to claim 2, wherein, in order to extract the distribution regions of volumes with the initial points of the regions at the positions of the local maximum values and at the positions of the local minimum values, the software establishes boundaries of the distribution regions and the regions by sequentially expanding the distribution regions while checking relationships with respect to the volume between adjacent nodes on the computational mesh.

8. The software for adjusting magnetic homogeneity according to claim 2, wherein, in the display step, the positions of the local maximum values, the positions of the local minimum values, or the results of the addition visually indicate two dimensional dispositions in an image corresponding to shim trays.

9. The software for adjusting magnetic homogeneity according to claim 8, wherein the local maximum values or the local minimum values are displayed by different symbols depending on positive magnetization or negative magnetization.

10. A method for adjusting magnetic homogeneity for a magnetic device having a magnetic field generation source for generating a magnetic field space and a magnetic field homogeneity adjuster for making magnetic field strength distribution, formed in the magnetic field space, homogeneous by disposing magnetic members outside the magnetic field space, wherein the method calculates and displays positions and volumes of the magnetic members to be disposed on the magnetic field homogeneity adjuster to make the magnetic field strength distribution homogeneous, based on the magnetic field strength distribution,
the method comprising:
an extraction process of extracting, from distribution of volumes of magnetic members calculated on a computational mesh, respective distribution regions of the volumes with initial points of the regions at positions of local maximum values and at positions of local minimum values of the volumes;
an addition process of adding the volumes of magnetic members distributed in the respective distribution regions; and
a display process of displaying positions of the magnetic members and results of adding the volumes together with the corresponding positions of the local maximum values or the corresponding positions of the local minimum values.

11. A magnetic field homogeneity adjustment device for a magnetic device having a magnetic field generation source for generating a magnetic field space and a magnetic field homogeneity adjuster for making magnetic field strength distribution, formed in the magnetic field space, homogeneous by disposing magnetic members outside the magnetic field space, wherein the magnetic field homogeneity adjustment device calculates and displays positions and volumes of the magnetic members to be disposed on the magnetic field homogeneity adjuster to make the magnetic field strength distribution homogeneous, based on the magnetic field strength distribution,
the magnetic field homogeneity adjustment device comprising:
an extraction section for extracting, from distribution of volumes of magnetic members calculated on a computational mesh, respective distribution regions of the volumes with initial points of the regions at local maximum values and at local minimum values of the volumes;
an addition section for adding the volumes of magnetic members distributed in the respective distribution regions; and
a display section for displaying positions of the magnetic members and results of adding the volumes together with the corresponding positions of the local maximum values or the corresponding positions of the local minimum values.

12. A magnetic device, comprising:
the magnetic field homogeneity adjustment device according to claim 11.

13. A magnetic resonance imaging (MRI) apparatus, comprising the magnetic device according to claim 12.
